(19) United States
(12) Patent Application Publication
(10) Pub. No.: US 2026/0248335 A1
(43) Pub. Date: Aug. 27, 2026

(54) VACUUM CLEANER AND CONTROL METHOD THEREFOR

(71) Applicant: LG ELECTRONICS INC., Seoul (KR)

(72) Inventors: Seungjin AHN, Seoul (KR); Hyungyul MAENG, Seoul (KR)

(73) Assignee: LG ELECTRONICS INC., Seoul (KR)

(21) Appl. No.: 18/872,616

(22) PCT Filed: May 4, 2023
(86) PCT No.: PCT/KR2023/006101

§ 371 Date: Dec. 6, 2024

(30) Foreign Application Priority Data
Jun. 8, 2022 (KR) 10-2022-0069472

(51) Int. Cl. A47L 9/28; A47L 9/00; A47L 9/04; G01D 5/14

(52) U.S. Cl. CPC A47L 9/2831; A47L 9/0063; A47L 9/0472; A47L 9/2826; A47L 9/2852; A47L 9/2857; A47L 9/2873; A47L 9/2894; G01D 5/14; A47L 2201/022; A47L 2201/04; A47L 2201/06

(57) ABSTRACT

A vacuum cleaner according to one embodiment of the present invention is characterized in that whether to output a cleaning cloth replacement signal notifying about the replacement of a cleaning cloth is determined on the basis of the value of a mop motor (182) current measured by a current sensor.

### TECHNICAL FIELD

The present disclosure relates to a cleaner and a control method thereof, and more particularly, to a cleaner and a control method thereof capable of informing the time of replacement of a cleaning cloth.

### BACKGROUND ART

In general, a mobile robot drives by itself within an area and performs a designated operation.

For example, a cleaning robot automatically cleans by sucking in foreign substances, such as dust from a floor surface. In addition, a lawn mower robot drives around an area and mows the lawn, and a wet cleaning robot cleans the floor surface using a cleaning cloth. In some cases, foreign substances may be sucked in from the front of a mobile robot, and a cleaning cloth may be mounted on the rear of the mobile robot to perform dry and wet cleaning.

Among these mobile robots, the wet cleaning robot moves around an area, while wiping the floor surface and performs wet cleaning.

Korean Application Publication No. 10-2014-0015069 relates to a water cleaning cloth robot cleaner, which enables water cleaning cloth cleaning to be performed clearly and quickly through soaking and wiping processes, and a water tank is formed on a cleaning cloth plate and a water cleaning cloth is formed with a water wiping portion of a water-applying portion and performs cleaning through the soaking and wiping processes.

Such a robot cleaner has a problem in that, since a certain amount of pressure is not applied to the floor surface, friction with the floor surface is small, so the effect of removing foreign substances is low and efficient cleaning is not performed accordingly.

Meanwhile, Korean Application Publication No. 2019-007608 relates to a robot cleaner, which is configured to include first and second rotating members capable of fixing a cleaner and include first and second rotating axes that rotate each rotating member and to move by the rotation of the rotating members.

In the related art robot cleaner, when the cleaning cloth is worn during wet cleaning, the friction between the floor and the cleaning cloth decreases.

The related art robot cleaners have a problem in that they cannot clean and may slip because the friction with the floor surface decreases due to wear of the cleaning cloth, and when slipping occurs, not only does the cleaning fail, but the current location cannot be determined and normal driving cannot be controlled.

In addition, in the case of a mobile robot that drives using two cleaning cloths and the friction between the two cleaning cloths and the floor, if only one of the two cleaning cloths is worn out, the robot cleaner cannot drive in a desired direction.

### PRIOR ART DOCUMENT

### Patent Document

Korean Application Publication No. 10-2014-0015069
Korean Application Publication No. 10-2019-007608

### DETAILED DESCRIPTION OF INVENTION

### Technical Problems

According to an embodiment of the present disclosure, the present disclosure provides a vacuum cleaner and a control method thereof capable of informing a user of the time to replace a cleaning cloth, thereby solving a problem of not cleaning due to wear of the cleaning cloth and a problem of unstable driving.

According to another embodiment of the present disclosure, the present disclosure provides provide a cleaner and a control method thereof capable of informing a user of the exact wear and replacement time of a cleaning cloth according to a floor material and a location of the cleaner.

According to another embodiment of the present disclosure, the present disclosure provides a cleaner and a control method thereof capable of informing a user of the replacement time of a cleaning cloth and the expected life of the cleaning cloth through various output parts, so that the user may easily recognize the time to replace the cleaning cloth and prepare for the replacement of the cleaning cloth.

The technical problems of the present disclosure are not limited to the technical problems mentioned above, and other technical problems that are not mentioned will be clearly understood by those skilled in the art from the description below.

### Technical Solution

According to an embodiment of the present, a cleaner determines whether to output a cleaning cloth replacement signal notifying about replacement of a cleaning cloth based on a current value of a mop motor measured by a current sensor.

In an aspect, a cleaner includes: a body; a rotary mop, on which a cleaning cloth is mounted, including a rotary plate rotatably installed on the body; a mop motor providing driving force to the rotary mop; a mop sensor measuring revolutions per minute (RPM) of the mop motor; a current sensor measuring a current value of the mop motor; and a controller determining whether to output a cleaning cloth replacement signal notifying about replacement of the cleaning cloth based on the current value of the mop motor measured by the current sensor.

The controller may output the cleaning cloth replacement signal when the current value of the mop motor measured while rotating the mop motor at a reference RPM is less than a reference current value.

The reference current value is set according to a floor material detected by a floor material detection sensor.

The floor material detection sensor may include a floor camera acquiring a floor image, and the controller may calculate roughness of a floor from the acquired floor image and determine a floor material through the roughness.

The cleaning cloth replacement signal may control ON and OFF of the mop motor repeatedly a preset number of times.

The cleaner may further include: an output part outputting a notification to notify of cleaning cloth replacement according to the cleaning cloth replacement signal.

The output part may include at least one of a speaker outputting auditorily recognizable information and a display outputting visually recognizable information.

The controller may control the output part to output an expected lifespan of the cleaning cloth according to the current value of the mop motor, when the current value of the mop motor is less than a reference current value while rotating the mop motor at a reference RPM.

The controller determines whether to output the cleaning cloth replacement signal when a smart diagnosis command is input through the input part.

The controller controls the mop motor to drive the body, and when a smart diagnosis command is input through the input part, the controller may move the body to a preset smart diagnosis location and then determine whether to output the cleaning cloth replacement signal.

The smart diagnosis location may be a charging station charging a battery of the body.

When an initial mop data collection command is input through the input part, the controller may control the current sensor to measure an initial current value of the mop motor when the mop motor rotates at a reference RPM.

The controller, while rotating the mop motor at the reference RPM at the location where the initial current value is measured, may output the cleaning cloth replacement signal when the current value of the mop motor is less than the reference current value.

The reference current value may be set in proportion to the initial current value.

The controller may control the mop motor to drive the body, and when the initial mop data collection command is input, the controller moves the body to a preset smart diagnosis location and then measures the initial current value.

The rotary mop may include a first rotary plate to which a first cleaning cloth is attached and a second rotary plate to which a second cleaning cloth is attached, and the body may be driven by rotation of the first rotary plate and the second rotary plate.

In another aspect, a cleaner includes: a body; a rotary mop including a rotary plate rotatably installed on the body; a mop motor providing driving force to the rotary mop; a current sensor measuring a current value of the mop motor; and a controller determining whether to output a cleaning cloth replacement signal notifying about replacement of a cleaning cloth based on a current value of the mop motor measured by the current sensor.

In another aspect, a control method of a cleaner includes: a rotation operation of rotating a mop motor at a reference revolutions per minute (RPM); a current measurement operation of measuring a current value of the mop motor when the mop motor rotates at the reference RPM; and an output operation of outputting a notification for notifying about replacement of the cleaning cloth when the measured current value of the mop motor is less than a reference current value.

The control method may further include: a reference current value calculation operation of detecting a floor material and calculating the reference current value.

The control method may further include: a moving operation of moving a body to a smart diagnosis location before the rotation operation.

In the output operation, ON and OFF of the mop motor may be repeated a preset number of times.

### Effect of Invention

In the present disclosure, a current value of the mop motor may be measured to inform the user of the time to replace a cleaning cloth, thereby solving the problem of not cleaning due to wear of the cleaning cloth and the problem of unstable driving.

In the present disclosure, since a material of the floor is detected, while the cleaner determines the wear of the cleaning cloth, a pre-stored reference current value according to a floor material may be used, so that the replacement time of the cleaning cloth may be informed accurately regardless of the floor material.

In addition, in the present disclosure, the cleaner may store a smart diagnosis location and measure an initial current value at the smart diagnosis location to set the reference current value, and through this, the cleaner returns to the smart diagnosis location to measure the wear of the cleaning cloth, and thus, the replacement time of the cleaning cloth may be informed regardless of the floor material, and there is no need to determine the floor material.

In addition, in the present disclosure, when the replacement time of the cleaning cloth arrives, the user may be informed of the time to replace the cleaning cloth by controlling the mop motor to be turned on and off periodically, a separate output part is not required.

The present disclosure has the advantage of not only informing the user of the replacement time of the cleaning cloth, but also informing the user of the expected lifespan of the cleaning cloth in advance, so that the user may estimate the replacement time of the cleaning cloth and prepare a replacement cleaning cloth in advance.

### BRIEF DESCRIPTION OF THE DRAWING

FIG. 1 is a perspective view illustrating a cleaner according to an embodiment of the present disclosure.

FIG. 2 is a perspective view illustrating a bottom surface of a cleaner according to an embodiment of the present disclosure.

FIG. 3 is an exploded perspective view of a mop module including a rotary mop of FIG. 2.

FIG. 4 is a block diagram illustrating a configuration of a cleaner according to an embodiment of the present disclosure.

FIG. 5 is a block diagram illustrating a configuration of a cleaning part of a cleaner according to an embodiment of the present disclosure.

FIG. 6 is a diagram illustrating a current value of a mop motor when a new cleaning cloth is used.

FIG. 7 is a diagram illustrating a current value of a mop motor when a worn cleaning cloth is used.

FIG. 8 is a flowchart illustrating a control method of a cleaner according to an embodiment of the present disclosure.

FIG. 9 is a flowchart illustrating a control method of a cleaner according to another embodiment of the present disclosure.

FIG. 10 is a perspective view of a cleaner according to another embodiment of the present disclosure.

FIG. 11 is an exploded perspective view of a water cleaning module of the cleaner illustrated in FIG. 10.

### BEST MODE FOR CARRYING OUT THE INVENTION

Advantages and features of the present disclosure and methods of accomplishing the same will be apparent by referring to embodiments described below in detail in connection with the accompanying drawings. However, the present disclosure is not limited to the embodiments disclosed below and may be implemented in various different forms. The embodiments are provided only for completing the disclosure of the present disclosure and for fully representing the scope of the present disclosure to those skilled in the art. A control configuration of the present disclosure may be configured by at least one processor.

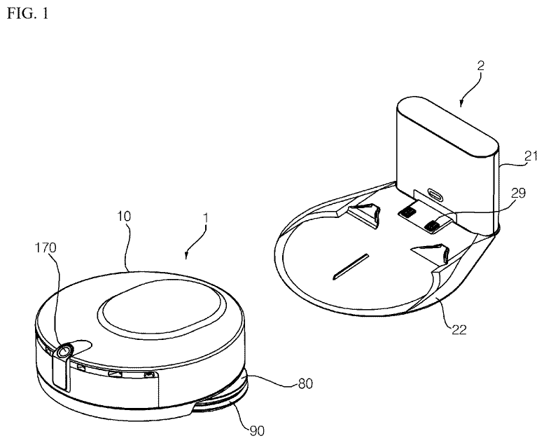

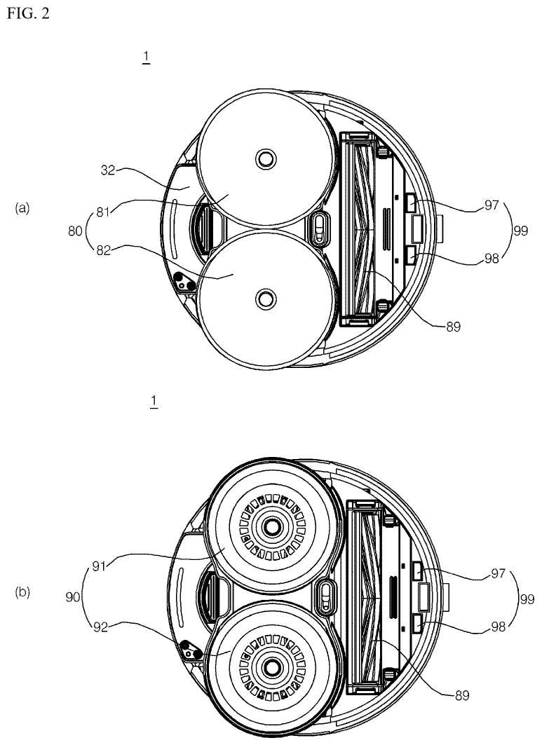

FIG. 1 is a perspective view illustrating a cleaner according to an embodiment of the present disclosure, and FIG. 2 is a diagram illustrating a bottom surface of a cleaner according to an embodiment of the present disclosure. The cleaner may include a mobile robot that moves and cleans on its own. Hereinafter, descriptions are given based on the mobile robot.

Referring to FIG. 1 and (a) and (b) of FIG. 2, a mobile robot 1 according to an embodiment of the present disclosure moves in an area and removes foreign substances from a floor surface, while driving.

In addition, the mobile robot 1 stores charging power supplied from a charging station 2 in a battery (not shown) and drives in an area.

The mobile robot 1 includes a body 10 that performs a designated operation, an obstacle detector (not shown) placed in front of the body 10 to detect obstacles, and an image acquisition part 170 that captures an image. The body 10 forms an exterior and includes a casing (not shown) that forms a space in which components constituting the body 10 are stored internally, a rotary mop 80 provided to be rotatable, a roller 89 that assists movement and cleaning of the body 10, and a charging terminal 99 that supplies charging power from a charging station 2.

In addition, the mobile robot 1 may further include a water tank 32 that is placed inside the body 10 to store water, a pump (not shown) that supplies water stored in the water tank to the rotary mop 80, and a connecting hose (not shown) that forms a connecting path connecting the pump and the water tank 32 or the pump and the rotary mop 80. In some cases, a valve that controls the water supply may be further provided.

The rotary mop 80 is placed in the casing and is formed toward the floor surface so that a cleaning cloth may be detachably attached. The rotary mop is placed symmetrically on the lower side of the body 10. The rotary mop 80 is placed in front of the water tank 32.

The rotary mop 80 moves by utilizing frictional force with the floor surface generated by the movement of rotating clockwise or counterclockwise when viewed from above, and wipes the floor with a cleaning cloth to cleans the floor. The rotary mop 80 is provided to rotate around a rotation axis that extends substantially in an up-down direction.

The rotary mop 80 includes a first rotary plate 81 and a second rotary plate 82, and allows the body 10 to move along the floor of the area through rotation.

The body 10 moves forward, backward, left, and right as the first rotary plate 81 and the second rotary plate 82 of the rotary mop 80 rotate around the rotation axis. In addition, the body 10 performs wet cleaning by removing foreign substances from the floor surface by the attached cleaning cloth as the first and second rotary plates rotate.

The body 10 may include a driver (not shown) that drives the first rotary plate 81 and the second rotary plate 82. The driver may include at least one motor.

The rotary mop 80 may be disposed so that each lower surface is inclined.

The lower surface of the first rotary plate 81 generally forms a downward slope toward the left. The lower surface of the second rotary plate 82 generally forms a downward slope toward the right. The lower surface of the first rotary plate 81 forms a lowest point on a left portion. The lower surface of the first rotary plate 81 forms a highest point on a right portion. The lower surface of the second rotary plate 82 forms a lowest point on the right portion. The lower surface of the second rotary plate 82 forms a highest point on the left portion. For example, the body 10 may move forward and backward as the first rotary plate 81 rotates in the first direction at a first rotation speed and the second rotary plate 82 rotates in the second direction at the first rotation speed. In addition, the body 10 may move left and right by setting the rotation speeds of the first rotary plate and the second rotary plate to be different or setting the rotation directions of the first rotary plate and the second rotary plate to be the same.

In addition, the body 10 may further include a tilting frame (not shown). The tilting frame is disposed to be tiltable within a predetermined angle range with respect to the rotary mop 80. The tilting frame allows an inclination angle to be changed according to the condition of the floor. The tilting frame may perform a suspension function (supporting the weight and simultaneously alleviating up-and-down vibration) of the rotary mop 80.

The roller 89 rotates while driving, collects foreign matter on the floor, and stores the collected foreign matter in a dust bin (not shown).

A control panel including an input part (not shown) for receiving various commands for controlling the mobile robot 1 from the user may be provided on the upper surface of the casing.

In addition, an image acquisition part 170 and an obstacle detector (not shown) are arranged on the front or upper surface of the body.

The obstacle detector detects obstacles located in a driving direction or around the body 10.

The image acquisition part 170 captures images of an indoor area. Based on the images captured through the image acquisition unit, not only the indoor area may be monitored, but also obstacles around the body may be detected.

The image acquisition part 170 is disposed toward a front-upper direction at a predetermined angle to capture images of the front and upper side of the mobile robot. In addition, the image acquisition part may capture 360 degrees.

The image acquisition part may further include a separate camera for capturing the front. The image acquisition part may be positioned in an upper portion of the body 10 and may be provided to face the ceiling, and in some cases, a plurality of cameras may be provided separately. In addition, the image acquisition part may be provided with a separate camera that images the floor.

The mobile robot 1 may further include a location acquisition means (not shown) for acquiring current location information. The mobile robot 1 may include GPS and UWB to determine the current location. In addition, the mobile robot 1 may determine the current location using an image.

The body 10 is equipped with a rechargeable battery (not shown), and the charging terminal 99 of the battery may be connected to a commercial power source (e.g., a power outlet in a home), or the body 10 may be docked to a charging station 2 connected to a commercial power source, so that the charging terminal may be electrically connected to the commercial power source through contact with the terminal 29 of the charging station, and the battery may be charged by charging power supplied to the body 10. In addition, the charging station 2 may include a mounting pad 22 on which the cleaning cloth of the mobile robot is mounted.

Electrical components constituting the mobile robot 1 may be supplied with power from the battery, and therefore, the mobile robot 1 may drive on its own, while the battery is charged and electrically separated from the commercial power supply.

Hereinafter, the mobile robot 1 is described as a wet cleaning mobile robot as an example, but the mobile robot 1 is not limited thereto and may be any robot that autonomously drives in an area and detects sound.

The rotary mop 80 includes the first rotary plate 81 and the second rotary plate 82.

The first rotary plate 81 and the second rotary plate 82 may have cleaning cloths 91 and 92 (90) attached thereto, respectively.

The rotary mop 80 is configured so that the cleaning cloth may be detachably attached. In the rotary mop 80, mounting members for attaching the cleaning cloths to the first rotary plate 81 and the second rotary plate 82 may be provided, respectively. For example, the rotary mop 80 may be provided with mounting members, such as Velcro and fitting members to attach and fix the cleaning cloth. In addition, the rotary mop 80 may further include a cleaning cloth frame (not shown) as a separate auxiliary means for fixing the cleaning cloth to the first rotary plate 81 and the second rotary plate 82.

The cleaning cloth 90 absorbs water and removes foreign substances through friction with the floor surface. The cleaning cloth 90 may include a microfiber or fabric-shaped pad, and may be formed of a material, such as cotton or cotton blend. Any material including a certain percentage or more of moisture and having a certain density may be used as the cleaning cloth, and the material is not limited.

The cleaning cloth 90 receives water from a water tank 32 through a connecting passage. Water may be supplied from the water tank 32 to the cleaning cloth 90 through the connecting passage by driving a pump. The cleaning cloth 90 is formed in a circular shape.

The shape of the cleaning cloth 90 is not limited to the drawing and may be formed in a square, polygon, etc., but considering a rotational motion of the first and second rotary plates, the cleaning cloth 90 is preferably formed in a shape that does not interfere with the rotational motion of the first and second rotary plates. In addition, the shape of the cleaning cloth may be changed to a circular shape by a separately provided cleaning cloth frame.

The rotary mop 80 is configured so that the cleaning cloth 90 comes into contact with the floor surface when it is mounted. The rotary mop 80 is configured so that a distance between the casing and the first and second rotary plates changes according to a thickness of the cleaning cloth, considering the thickness of the cleaning cloth.

The rotary mop 80 further includes a member that adjusts the distance between the casing and the rotary plate so that the cleaning cloth comes into contact with the floor surface and generates pressure on the first and second rotary plates toward the floor surface.

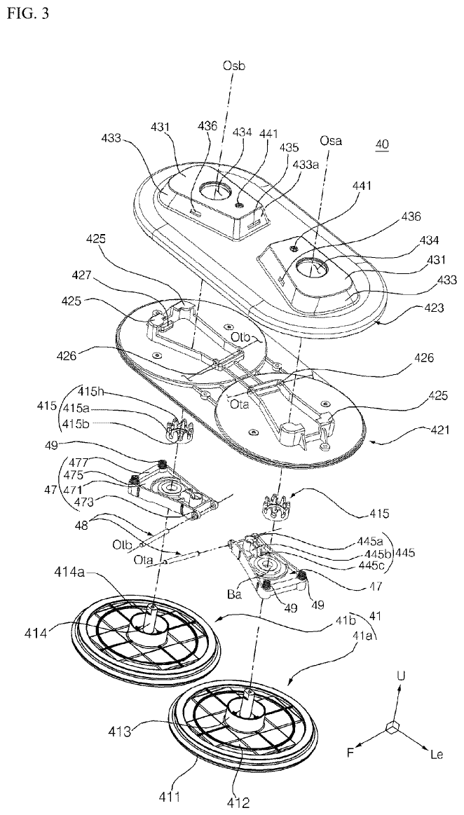

FIG. 3 is an exploded perspective view of a mop module including a rotary mop of the mobile robot of FIG. 2.

As shown in FIG. 3, the rotary mop 80 is included in a mop module 40.

The mop module 40 includes at least one cleaning cloth 90, 41, and 411 provided to clean the floor while rotating and at least one rotary mop 80 provided to contact the floor while rotating clockwise or counterclockwise when viewed from above.

The rotary mop includes first rotary plates 81 and 41a and second rotary plates 82 and 41b. In the present embodiment, the rotary mop 80 is provided to rotate around rotation axes Osa and Osb that extend substantially in the up-down direction.

The mop module 40 is disposed below the body 10. The mop module 40 is disposed at the rear of a collection module 50.

The first rotary plate 41a and the second rotary plate 41b each include a cleaning cloth 411, a rotary plate 412, and a spin shaft 414. The first rotary plate 41a and the second rotary plate 41b each include a water supply receiving part 413. The first rotary plate 41a and the second rotary plate 41b each include a driven joint 415. The description of the cleaning cloth 411, the rotary plate 412, the spin shaft 414, the water supply receiving part 413, and the driven joint 415 described below may be understood as components that the first rotary plate 41a and the second rotary plate 41b each have.

The body 10 and the mob module 40 may be detachably connected to each other.

A state in which the body 10 and the mob module 40 are coupled to each other may be referred to as a ‘coupled state’ hereinafter. In addition, a state in which the body 10 and the mob module 40 are separated from each other may be referred to as a ‘separated state’ hereinafter. The mobile robot 1 includes a detachable module (not shown) that detachably attaches the mob module to the body. The detachable module may release the mob module 40 from the body 10 in the coupled state. The detachable module operates so that the mob module 40 and the body 10 may be detachably attached to each other. The detachable module may cause the mob module 40 to be attached to the body 10 in the separated state. The detachable module may be disposed across a gap between the water tank 32 and the battery Bt.

The mobile robot 1 includes a base (not shown) that forms a lower surface of the body 10. The base forms the lower surface, front surface, rear surface, left surface, and right surface of the body 10. The mob module 40 is coupled to the base. The collection module (not shown) is coupled to the base. A controller 110 and the battery Bt are arranged in an internal space formed by the case 31 and the base.

The mobile robot 1 includes a module housing 42 that forms the exterior of the mob module 40. The module housing 42 is disposed on the lower side of the body 10.

The mob module 40 includes a pair of body mounting parts (not shown) arranged spaced apart from each other. The pair of body mounting parts correspond to a pair of rotary mobs 41a and 41b. The pair of body mounting parts correspond to a pair of module mounting parts (not shown).

The module mounting parts form a joint hole (not shown) in which at least a portion of a driving joint (not shown) is exposed. The driving joint (not shown) may be disposed by passing through the joint hole. The driving joint is coupled with the driven joint 415 to transmit driving force of the driver (not shown) to the rotary mob.

A protruding engagement portion (not shown) is provided on a surface of any one of the module mounting part and the body mounting part, and recessed engagement counterpart portions 435 and 436 are provided on the other surface to engage with the engagement portion in the coupled state.

The body mounting part 43 includes an upper surface portion 431 forming an upper side surface. The upper surface portion 431 faces upward. The upper surface portion 431 may be formed horizontally. The upper surface portion 431 is disposed on the upper side of a peripheral portion 433.

The body mounting part 43 includes a peripheral portion 433 disposed along the perimeter of the upper surface portion 431. The peripheral portion 433 forms an inclined surface extending from the upper side surface of the module housing 42 to the upper side surface 431. The peripheral portion 433 has a slope that increases from the upper side surface of the module housing 42 to the upper surface portion 431. The peripheral portion 433 is disposed to surround the upper surface portion 431.

The body mounting part 43 includes an engagement counterpart surface 433a that contacts the engagement surface 363a in the aforementioned coupled state. A pair of body mounting parts 43 includes a pair of engagement counterpart surfaces 433a. The pair of engagement counterpart surfaces 433a are arranged to face each other diagonally left and right. The pair of engagement counterpart surfaces 433a are arranged between the pair of body mounting parts 43. The engagement counterpart surface 433a is disposed in an area near the other adjacent body mounting part 43 in the periphery portion 433 of one body mounting part 43. The engagement counterpart surface 433a is disposed in an area relatively close to the central vertical plane Po of the periphery portion 433. The engagement counterpart surface 433a constitutes a portion of the periphery portion 433.

The body mounting part 43 forms a driving hole 434 through which at least a portion of the driven joint 415 is exposed. The driving hole 434 is formed in the upper surface portion 431. In the aforementioned coupled state, the driving joint may be inserted into the driving hole 434 and connected to the driven joint 415.

The mob module 40 includes at least one rotary mob 80. At least one rotary mob 80 may include a pair of rotary mobs 80. The pair of rotary plates 80 are arranged symmetrically left and right based on a virtual central vertical plane. The first rotary plate 41a and the second rotary plate 41b are arranged symmetrically left and right.

A lower side surface of the first rotary plate 41a and a lower side surface of the second rotary plate 41b are arranged to be inclined. The lower side surface of the first rotary plate 41a forms a downward slope overall toward the left. The lower side surface of the second rotary plate 41b forms a downward slope overall toward the right.

The lower side surface of the first rotary plate 41a forms a lowest point on the left portion. The lower side surface of the first rotary plate 41a forms a highest point on the right. The lower side surface of the second rotary plate 41b forms a lowest point on the right. The lower side surface of the second rotary plate 41b forms a highest point on the left.

The movement of the mobile robot 1 is implemented by frictional force with the ground generated by the mob module 40.

The mob module 40 may generate a ‘forward movement frictional force’ to move the body 10 forward or a ‘backward movement frictional force’ to move the body backward. The mob module 40 may generate a ‘leftward moment frictional force’ to turn the body 10 left or a ‘rightward moment frictional force’ to turn the body 10 right. The mob module 40 may generate frictional force that combines either one of the forward movement frictional force and the backward movement frictional force, and either one of the leftward moment frictional force and the rightward moment frictional force.

In order for the mob module 40 to generate the aforementioned forward movement frictional force, the first rotary plate 41a may be rotated in a first positive direction at a predetermined rpm R1 and the second rotary plate 41b may be rotated in a second positive direction at the aforementioned rpm R1.

In order for the mob module 40 to generate the aforementioned backward movement frictional force, the first rotary plate 41a may be rotated in a first reverse direction at a predetermined rpm and the second rotary plate 41b may be rotated in A second reverse direction at the aforementioned rpm R2.

The rotary mop 80 includes the driven joint 415 rotates in mesh with the driving joint. The driving joint is exposed to the outside of the body 10. At least a portion of the driven joint 415 is exposed to the outside of the mop module 40.

In the separated state, the driving joint and the driven joint 415 are separated from each other. In the coupled state, the driving joint and the driven joint 415 are engaged.

One of the driving joint and the driven joint 415 includes a plurality of driving protrusions (not shown) arranged in a circumferential direction based on one of the rotation axes, and the other forms a plurality of driving grooves 415h arranged in a circumferential direction based on the other rotation axis.

The plurality of driving protrusions are arranged to be spaced apart from each other at a predetermined interval. The plurality of driving grooves 415h are arranged to be spaced apart from each other at a predetermined interval. In the coupled state, the driving protrusions are provided to be inserted into the driving grooves 415h.

One of the driving joint and the driven joint 415 includes a plurality of driving protrusions 65a arranged to be spaced apart from each other in the circumferential direction based on one of the rotation axes, and the other includes a plurality of opposing protrusions 415a arranged to be spaced apart from each other in the circumferential direction based on the other rotation axis. The plurality of opposing protrusions 415a protrude in one of the directions. The protruding ends of the opposing protrusions 415a are formed to be rounded. The protruding ends of the opposing protrusions 415a are formed to be rounded in the arrangement direction of the plurality of opposing protrusions 415a. The protruding ends of the opposing protrusions 415a have corner portions that are rounded in the direction of the adjacent opposing protrusions 415a based on the central axis of the protruding direction. Through this, when changing from the separated state to the coupled state, the driving protrusion 65a may smoothly move along the rounded protruding end of the opposing protrusion 415a and be inserted into the driving groove 415h.

In the present embodiment, the driving joint includes the driving protrusion 65a, and the driven joint 415 forms the driving groove 415h. In the present embodiment, the driven joint 415 includes the opposing protrusion 415a. Hereinafter, the description is given based on the present embodiment.

The driven joint 415 is fixed to an upper end of the spin shaft 414. The driven joint 415 includes a driven shaft portion 415b fixed to the spin shaft. The driven joint 415 includes an opposing protrusion 415a protruding from the driven shaft portion 415b. The opposing protrusion 415a protrudes in the direction toward the driving joint in the up-down direction from the driven shaft 415b.

The module housing 42 connects a pair of rotary mops 41a and 41b. The pair of rotary mops 41a and 41b are separated from the body 10 together by the module housing 42 and are coupled together to the body 10. A body mounting part 43 is disposed on the upper side of the module housing 42. The rotary mop 80 may be rotatably supported by the module housing 42.

The rotary mop 80 may be disposed while penetrating through the module housing 42.

The module housing 42 may include an upper cover 421 forming an upper portion and a lower cover 423 forming a lower portion. The upper cover 421 and the lower cover 423 are coupled to each other. The upper cover 421 and the lower cover 423 form an internal space that accommodates a portion of the rotary shaft 80.

Suspension units 47, 48, and 49 may be arranged in the module housing 42. The suspension units 47, 48, and 49 may be placed in the internal space formed by the upper cover 421 and the lower cover 423. The suspension units 47, 48, and 49 support the spin shaft 414 to move up and down within a predetermined range. The suspension units 47, 48, and 49 according to the present embodiment include a tilting frame 47, a tilting shaft 48, and an elastic member 49.

The module housing 42 may include a limiter that limits a rotation range of the tilting frame 47.

The limiter may include a lower limiter 427 that limits a downward rotation range of the tilting frame 47. The lower limiter 427 may be disposed in the module housing 42. The lower limiter 427 is provided to contact the lower limiter contact portion 477 when the tilting frame 47 is rotated downward to the maximum. When the mobile robot 1 is normally disposed on an external horizontal surface, the lower limiter contact portion 477 is spaced from the lower limiter 427. When there is no force pushing upward from the lower surface of the rotary mop 80, the tilting frame 47 rotates to the maximum angle, the lower limiter contact portion 477 comes into contact with the lower limiter 427, and the inclination angle becomes the largest.

The limiter may include an upper limiter (not shown) that limits an upward rotation range of the tilting frame 47. In the present embodiment, the upward rotation range of the tilting frame 47 may be limited by the close contact between the driving joint and the driven joint 415. When the mobile robot 1 is normally placed on the external horizontal surface, the driven joint 415 is in maximum contact with the driving joint and the inclination angle is the smallest.

The module housing 42 includes a second support portion 425 that fixes the end of the elastic member 49. When the tilting frame 47 rotates, the elastic member 49 is elastically deformed or elastically restored by a first support portion 475 fixed to the tilting frame 47 and a second support portion 425 fixed to the module housing 42.

The module housing 42 includes a tilting shaft support portion 426 that supports the tilting shaft 48. The tilting shaft support portion 426 supports both ends of the tilting shaft 48.

The mob module 40 includes a module water supplier 44 that guides water flowing in from the water tank 32 to the rotary mob 80 in the coupled state. The module water supplier 44 guides water from the upper side to the lower side. A pair of module water supply units (not shown) corresponding to the pair of rotary mobs 41a and 41b may be provided.

The module water supplier (not shown) includes a water supply counterpart portion 441 that receives water from the water tank 32. The water supply counterpart portion 441 is provided to be connected to a water supply connection portion (not shown).

The module water supplier 44 includes a water supply guide portion 445 that guides water flowing in to the water supply counterpart portion 441 to the rotary mob 80. Water flowing into the water supply counterpart portion 441 flows into the water supply induction portion 445 through a water supply delivery portion 443.

The water supply induction portion 445 is placed on the tilting frame 47. The water supply induction portion 445 is fixed to the frame base 471. Water flows into a space formed by the water supply induction portion 445 through the water supply counterpart portion 441 and the water supply delivery portion 443. The water supply induction portion 445 may minimize water splashing and induce all the water to flow into the water supply receiving part 413.

The water supply induction portion 445 may include an inlet portion 445a that forms a space that is sunken from the upper side to the lower side. The inlet portion 445a may accommodate a lower end of the water supply delivery portion 443. The inlet portion 445a may form a space with an open upper side. Water passing through the water supply delivery portion 443 flows in through the upper opening of the space of the inlet portion 445a. The space of the inlet portion 445a is connected to a flow path in which a flow path portion 445b is formed on one side.

The water supply induction portion 445 may include a flow path portion 445b connecting the inlet portion 445a and an outlet portion 445c. One end of the flow path portion 445b is connected to the inlet portion 445a, and the other end of the flow path portion 445b is connected to the outlet portion 445c. The space formed by the flow path portion 445b becomes a water movement passage. The space of the flow path portion 445b is connected to the space of the inlet portion 445a. The flow path portion 445b may be formed in a channel shape with an open upper side. The flow path portion 445b may have a slope that decreases from the inlet portion 445a to the outlet portion 445c.

The water supply induction portion 445 may include an outlet portion 445c that discharges water into a water supply space Sw of the water supply receiving part 413. A lower end of the outlet portion 445c may be disposed within the water supply space Sw. The outlet portion 445c forms a hole connected from the internal space of the module housing 42 to the upper space of the rotary plate 412. The hole of the outlet portion 445c vertically connects the two spaces. The outlet portion 445c forms a hole that vertically penetrates the tilting frame 47. The space of the flow path portion 445b is connected to the hole of the outlet portion 445c. The lower end of the outlet portion 445c may be disposed within the water supply space Sw of the water supply receiving part 413.

The tilting frame 47 is connected to the module housing 42 through the tilting shaft 48. The tilting frame 47 rotatably supports the spin shaft 414.

The tilting frame 47 is provided to be rotatable within a predetermined range based on the tilting rotation axes Ota and Otb. The tilting rotation axes Ota and Otb extend in a direction crossing the rotation axis Osa and Osb of the spin shaft 414. The tilting shaft 48 is disposed on the tilting rotation axes Ota and Otb. The tilting frame 47 on the left is provided to be rotatable within a predetermined range based on the tilting rotation axis Ota. The tilting frame 47 on the right is provided to be rotatable within a predetermined range based on the tilting rotation axis Otb.

The tilting frame 47 is disposed to be tiltable within a predetermined angle range with respect to the mob module 40. The tilting frame 47 allows the inclination angle to be changed according to the condition of the floor. The tilting frame 47 may perform a suspension function (supporting the weight and simultaneously alleviating vertical vibration) of the rotary mop 80.

The tilting frame 47 includes a frame base 471 forming a lower surface. The spin shaft 414 is disposed to penetrate the frame base 471 vertically. The frame base 471 may be formed in a plate shape that forms a thickness vertically. The tilting shaft 48 rotatably connects the module housing 42 and the frame base 471.

A bearing Ba may be provided between a rotating shaft support portion 473 and the spin shaft 414. The bearing Ba may include a first bearing B1 disposed on a lower side and a second bearing B2 disposed on an upper side.

A lower end of the rotating shaft support portion 473 is inserted into the water supply space Sw of the water supply receiving part 413. An inner circumferential surface of the rotating shaft support portion 473 supports the spin shaft 414.

The tilting frame 47 includes a first support portion 475 that supports one end of the elastic member 49. The other end of the elastic member 49 is supported by a second support portion 425 disposed in the module housing 42. When the tilting frame 47 tilts based on the tilting shaft 48, the location of the first support portion 475 changes and the length of the elastic member 49 changes.

The first support portion 475 is fixed to the tilting frame 47. The first support portion 475 is disposed on the left side of the left tilting frame 47. The first support portion 475 is disposed on the right side of the right tilting frame 47. The second support portion 425 is disposed on a left region of the first rotary plate 41a. The second support portion 425 is disposed on a right region of the second rotary plate 41b.

The first support portion 475 is fixed to the tilting frame 47. The first support portion 475 tilts together with the tilting frame 47 when the tilting frame 47 tilts. When the tilting angle is minimum, a distance between the first support portion 475 and the second support portion 425 is the shortest, and when the tilting angle is maximum, the distance between the first support portion 475 and the second support portion 425 is the farthest. The elastic member 49 is elastically deformed when the tilting angle is minimum to provide restoring force.

The tilting frame 47 includes a lower limiter contact portion 477 provided to be in contact with the lower limiter 427. The lower surface of the lower limiter contact portion 477 may be provided to be in contact with the upper side of the lower limiter 427.

The tilting shaft 48 is disposed in the module housing 42. The tilting shaft 48 becomes a rotation axis of the tilting frame 47. The tilting shaft 48 may be disposed to extend in a direction perpendicular to the inclination direction of the rotary mop 80. The tilting shaft 48 may be disposed to extend in a horizontal direction. In the present embodiment, the tilting shaft 48 is disposed to extend in a direction tilted at an acute angle in the forward-backward direction.

The elastic member 49 applies elastic force to the tilting frame 47. The elastic force is applied to the tilting frame 47 so that the inclination angle of the lower surface of the rotary mop 80 with respect to the horizontal plane increases.

The elastic member 49 is provided to expand when the tilting frame 47 rotates downward and contract when the tilting frame 47 rotates upward. The elastic member 49 enables the tilting frame 47 to operate in a cushioning (elastic) manner. The elastic member 49 applies a moment force to the tilting frame 47 in a direction in which the inclination angle increases.

The rotary mop 80 includes rotary plates 81, 82, and 412 provided to rotate on the lower side of the body 10. The rotary plate 412 may be formed as a circular plate-shaped member based on the spin shaft 414. The cleaning cloth 411 is fixed to the lower surface of the rotary plate 412. The rotary plate 412 rotates the cleaning cloth 411. The spin shaft 414 is fixed to the center of the rotary plate 412.

The rotary plate 412 includes the second rotary plate 412 spaced apart from the first rotary plates 81 and 412. The lower surface of the first rotary plate 412 may form a downward slope in a left-forward direction, and the lower surface of the second rotary plates 82 and 412 may form a downward slope in the right-forward direction.

The rotary plate 412 includes a cleaning cloth fixing portion 412c that fixes the cleaning cloths 90 and 411. The cleaning cloth fixing portion 412c may fix the cleaning cloth 411 in a detachable manner. The cleaning cloth fixing portion 412c may be a Velcro or the like disposed on the lower surface of the rotary plate 412. The cleaning cloth fixing portion 412c may be a hook or the like disposed on the edge of the rotary plate 412.

A water supply hole 412a that penetrates the rotary plate 412 vertically is formed. The water supply hole 412a connects the water supply space Sw and the lower side of the rotary plate 412. Through the water supply hole 412a, water in the water supply space Sw moves to the lower side of the rotary plate 412. Through the water supply hole 412a, water in the water supply space Sw moves to the cleaning cloth 411. The water supply hole 412a is disposed at the center of the rotary plate 412. The water supply hole 412a is disposed at a location avoiding the spin shaft 414. Specifically, the water supply hole 412a is disposed at a location that does not overlap the spin shaft 414 in the vertical direction.

The rotary plate 412 may form a plurality of water supply holes 412a. A connecting portion 412b is disposed between the plurality of water supply holes 412a. The connecting portion 412b connects a centrifugal direction XO portion and a counter-centrifugal direction XI portion of the rotary plate 412 based on the water supply hole 412a. Here, the centrifugal direction XO refers to a direction away from the spin shaft 414, and the counter-centrifugal direction XI refers to a direction toward the spin shaft 414.

A plurality of water supply holes 412a may be spaced apart from each other in the circumferential direction of the spin shaft 414. A plurality of water supply holes 412a may be spaced apart from each other at a predetermined interval. A plurality of connecting portions 412b may be spaced apart from each other in the circumferential direction of the spin shaft 414. The water supply hole 412a is disposed between the plurality of connecting portions 412b.

The rotary plate 412 includes an inclined portion 412d disposed at the lower end of the spin shaft 414. Water in the water supply space Sw flows down along the inclined portion 412d by gravity. The inclined portion 412d is formed along the circumference of the lower end of the spin shaft 414. The inclined portion 412d forms a downward slope in the counter-centrifugal direction XI. The inclined portion 412d may form a lower surface of the water supply hole 412a.

The rotary mop 80 includes the cleaning cloth 411 coupled to the lower side of the rotary plate 412 and provided to contact the floor. The cleaning cloth 411 may be replaceably placed on the rotary plate 412. The cleaning cloth 411 may be detachably fixed to the rotary plate 412 by means of Velcro or a hook. The cleaning cloth 411 may be formed of only the cleaning cloth 411 or may include the cleaning cloth 411 and a spacer (not shown). The cleaning cloth 411 is a portion that directly comes into contact with the floor and cleans.

The rotary mop 80 includes the spin shaft 414 that rotates the rotary plate 412. The spin shaft 414 is fixed to the rotary plate 412 and transmits rotating power of a mob driver 60 to the rotary plate 412. The spin shaft 414 is connected to the upper side of the rotary plate 412. The spin shaft 414 is disposed at the upper center of the rotary plate 412. The spin shaft 414 is fixed to the rotation centers Osa and Osb (rotation axes) of the rotary plate 412. The spin shaft 414 includes a joint fixing portion 414a that fixes the driven joint 415. The joint fixing portion 414a is disposed at the upper end of the spin shaft 414.

The mob module 40 includes the water supply receiving part 413 disposed at the upper side of the rotary plate 412 and receiving water. The water supply receiving part 413 forms the water supply space Sw in which water is received. The water supply receiving part 413 surrounds the circumference of the spin shaft 414 but is spaced apart from the spin shaft 414 to form the water supply space Sw. The water supply receiving part 413 collects water supplied to the upper side of the rotary plate 412 in the water supply space Sw before passing through the water supply hole 412a. The water supply space Sw is disposed in the upper central portion of the rotary plate 412. The water supply space Sw has an overall cylindrical volume. The upper side of the water supply space Sw is open. Water is provided to flow into the water supply space Sw through the upper side of the water supply space Sw.

The water supply receiving part 413 protrudes upwardly from the rotary plate 412. The water supply receiving part 413 extends in the circumferential direction of the spin shaft 414. The water supply receiving part 413 may be formed in a ring-shaped rib shape. The water supply hole 412a is disposed on an inner lower surface of the water supply receiving part 413. The water supply receiving part 413 is disposed to be spaced apart from the spin shaft 414.

The lower end of the water supply receiving part 413 is fixed to the rotary plate 412. The upper end of the water supply receiving part 413 has a free end 463.

FIG. 4 is a block diagram briefly illustrating a configuration of a mobile robot according to an embodiment of the present disclosure.

As illustrated in FIG. 4, the mobile robot 1 includes a cleaning part 180, a data part 120, an obstacle detector 100, an image acquisition part 170, a sensor part 150, a communication part 130, an input part 160, an output part 190, and a controller 110 that controls the overall operation.

The input part 160 includes at least one input means, such as a button, switch, or touchpad to receive a user command. The input part may be provided at an upper end of the body 10 as described above.

The output part 190 includes a display, such as an LED or LCD, and displays an operation mode, reservation information, battery status, operation status, error status, etc. of the mobile robot 1. In addition, the output part 190 includes a speaker or buzzer and outputs predetermined sound effects, warning sounds, or voice guidance corresponding to an operation mode, reservation information, battery status, operation status, and error status.

In some cases, the mobile robot may further include an audio input part (not shown).

The audio input part includes at least one microphone and receives sound generated within a certain distance from the body 10 or within an area. The audio input part may further include a signal processing portion (not shown) that filters, amplifies, and converts input sound. The mobile robot 1 may recognize and operate a voice command input through the audio input part.

The data part 120 stores an acquired image input from the image acquisition part 170, stores reference data for an obstacle recognizer 111 to determine an obstacle, and stores obstacle information for the detected obstacle.

The data part 120 stores obstacle data for determining the type of obstacle, image data storing a captured image, and map data for an area. The map data includes obstacle information and stores various types of maps for a drivable area explored by the mobile robot.

The data part 120 may include images captured through the image acquisition part, such as still images, moving images, and panoramic images. In addition, the data part 120 stores control data for controlling the operation of the mobile robot, data according to a cleaning mode of the mobile robot, and detection signals, such as ultrasonic/laser signals by the sensor part 150.

In addition, the data part 120 stores data that may be read by a microprocessor and may include a hard disk drive (HDD), a solid state disk (SSD), a silicon disk drive (SDD), a ROM, a RAM, a CD-ROM, a magnetic tape, a floppy disk, and an optical data storage device.

The communication part 130 communicates with a terminal 300 in a wireless communication manner. In addition, the communication part 130 may be connected to the Internet through a home network and communicate with an external server (not shown) or the terminal 300 that controls a mobile robot.

The communication part 130 transmits a generated map to the terminal 300, receives a cleaning command from the terminal, and transmits data regarding the operating status and cleaning status of the mobile robot to the terminal. In addition, the communication part 130 may transmit information on obstacles detected during driving to the terminal 300 or the server. The communication part 130 includes a communication module, such as short-range wireless communication, such as Zigbee, Bluetooth, Wi-Fi, WiBro, etc., and transmits and receives data.

The communication part 130 may communicate with the charging station 2 and may receive a charging station return signal or a guide signal for docking to the charging station. The mobile robot 1 searches for the charging station and docks to the charging station based on a signal received through the communication part 130.

Meanwhile, the terminal 300 is a device equipped with a communication module for network connection, in which a program for controlling the mobile robot or an application for controlling the mobile robot is installed. As the terminal 300, a device, such as a computer, laptop, smartphone, PDA, tablet PC, etc. may be used. In addition, the terminal may also be a wearable device, such as a smart watch.

The terminal 300 may output a predetermined warning sound or display a received image according to the data received from the mobile robot 1.

The terminal 300 may receive data from the mobile robot 1, monitor the operating status of the mobile robot, and control the mobile robot 1 through control commands.

The terminal 300 may be directly connected to the mobile robot 1 in a one-to-one manner and may also be connected through a server, such as a home appliance management server.

The cleaning part 180 rotates the first rotary plate 81 and the second rotary plate 82 of the rotary mop 80 through the driver (not shown), thereby removing foreign substances on the floor surface according to a rotational motion of the attached cleaning cloth 90.

The body 10 moves by the rotational motion of the first and second rotary plates 81 and 82 of the cleaning part 180. Accordingly, the cleaning part 180 may operate as a traveling portion.

In addition, the cleaning part 180 may further include a water supplier (not shown) connected to the rotary mop 80 and supplying water to the cleaning cloth attached to the first and second rotary plates and a water tank 32. The water supplier may include a pump or a valve.

The cleaning part 180 may include a separate cleaning cloth tool for mounting the cleaning cloth on the rotary mop. The battery (not shown) supplies power necessary for the overall operation of the mobile robot 1 as well as the motor. When the battery is discharged, the mobile robot 1 may drive to return to the charging station for charging, and during the return driving, the mobile robot 1 may detect the location of the charging station by itself.

The charging station 2 may include a signal transmission portion (not shown) that transmits a predetermined return signal. The return signal may be an ultrasonic signal or an infrared signal but is not necessarily limited thereto.

The obstacle detector 100 inspects a pattern having a predetermined shape and acquires the inspected pattern as an image. The obstacle detector may include at least one pattern inspection portion (not shown) and a pattern acquisition unit.

In addition, the obstacle detector may include sensors, such as an ultrasonic sensor, a laser sensor, an infrared sensor, and a 3D sensor to detect a location of an obstacle located in the driving direction and a size of distance thereto. In addition, the obstacle detector 100 may detect an obstacle as an image for the driving direction. The sensor part and the image acquisition part may be included in the obstacle detector.

The sensor part 150 includes a plurality of sensors and detect an obstacle. The sensor part 150 detects an obstacle in the front, i.e., in the driving direction, using at least one of an ultrasonic sensor, a laser sensor, and an infrared sensor. The sensor part 150 may be used as an auxiliary means for detecting an obstacle that is not detected by the obstacle detector.

In addition, the sensor part 150 may further include a cliff detection sensor that detects whether there is a cliff on the floor within the driving area. When a signal transmitted is reflected and incident, the sensor part 150 inputs information on the presence of an obstacle or a distance to the obstacle as an obstacle detection signal to the controller 110.

The sensor part 150 includes at least one tilt sensor and detects a tilt of the body. When the body is tilted in the forward, backward, left, or right directions, the tilt sensor calculates a tilted direction and angle. The tilt sensor may be a tilt sensor, an acceleration sensor, etc., and the acceleration sensor may be any of the gyro-type, inertial-type, and silicon semiconductor-type.

The sensor part 150 may detect a rotation angle and movement distance of the body 10. The angle may be measured through a gyro sensor, and the movement distance may be measured through a laser OFS.

In addition, the sensor part 150 may detect the operating status and abnormality through a sensor installed inside the mobile robot 1.

In addition, the sensor part 150 may include a floor material detection sensor that detects a floor material. The floor material detection sensor detects a material of the floor on which the body is located and transmits the same to the controller 110.

Specifically, the floor material detection sensor includes a floor camera that acquires a floor image, and the controller 110 may calculate roughness of the floor from the acquired floor image and determine a floor material through the roughness. In addition, the controller 110 may estimate the floor material from the floor image through learning.

The image acquisition part 170 includes at least one camera.

The image acquisition part 170 may include a camera that converts an image of a subject into an electrical signal, converts the electrical signal into a digital signal, and then stores the digital signal in a memory device. The camera may include an image sensor (e.g., a CMOS image sensor) including at least one optical lens and a plurality of photodiodes (e.g., pixels) that form an image by light passing through the optical lens and a digital signal processor (DSP) that forms an image based on signals output from the photodiodes. The digital signal processor may generate not only still images but also moving images including frames composed of still images.

The image sensor is a device that converts an optical image into an electrical signal and includes a chip in which a plurality of photodiodes are integrated, and an example of a photodiode is a pixel. Charges are accumulated in each pixel by the image formed on the chip by light passing through the lens, and the charges accumulated in the pixels are converted into electrical signals (e.g., voltage). A charge coupled device (CCD) and a complementary metal oxide semiconductor (CMOS) are well known as image sensors.

The image acquisition part 170 continuously captures images when the mobile robot moves. In addition, the image acquisition part 170 may capture images at a predetermined period or at a predetermined distance. The image acquisition part 170 may set an image capture cycle according to a moving speed of the mobile robot.

The image acquisition part 170 may capture images of the front in the driving direction as well as an upward ceiling shape. The image acquisition part 170 stores images captured while the body is moving as image data in the data part 120.

The obstacle detector 100 inputs information on a location of a detected obstacle or a movement thereof to the controller 110. The sensor part 150 may input a detection signal for an obstacle detected by a sensor included therein to the controller 110. The image acquisition part 170 inputs a captured image to the controller 110.

The controller 110 controls the mobile robot to drive within a designated area among the driving areas.

The controller 110 processes data input by the operation of the input part 160 to set an operation mode of the mobile robot, outputs an operation status through the output part 190, and outputs warning sounds, sound effects, and voice guidance according to an operation status, error status, or obstacle detection through a speaker of the output part.

The controller 110 generates a map for the driving area based on the image acquired from the image acquisition part 170 and the obstacle information detected from the sensor part 150 or the obstacle detector 100. The controller 110 generates a map based on the obstacle information during driving within the area and may generate the map by determining the shape of the driving area from the image of the image acquisition unit.

The controller 110 recognizes an obstacle detected from the image acquisition part 170 or the obstacle detector 100 and controls the cleaner to perform a specific operation in response to the obstacle or change a path and move. In addition, the controller 110 may output a predetermined sound effect or warning sound through the output part as needed and control the image acquisition part to capture an image.

In addition, the controller 110 causes the cleaning part 180 to operate according to a cleaning command and move while cleaning the floor surface. The controller 110 determines a driving status based on whether the body 10 moves according to a designated driving path and whether it drives normally when the body 10 moves by the rotational motion of the cleaning part 180.

The controller 110 sets a movement path based on a specific destination and controls the body 10 to avoid obstacles while driving along the movement path.

The controller 110 determines that there is an abnormality in the driving status if the body 10 does not drive in a straight line and deviates from the path during straight driving.

If there is an abnormality in the driving status, the controller 110 determines the cause due to an abnormality in the driver provided in the cleaning part, an abnormality in the floor condition, or an unmounted cleaning cloth.

The controller 110 determines the driving status by comparing a set movement path with an actual driving path along which the body 10 has moved. The controller 110 determines whether the body 10 is driving according to the set movement path based on the change in location during movement and determines the driving status.

The controller 110 may determine that there is an abnormality in the driving status if the body 10 deviates to drive by a certain distance or more from the set movement path.

When an obstacle is detected based on the presence or absence of an obstacle, the controller 110 determines that the body drives normally, and if the body deviates from the movement path by a certain distance or more to move in a state in which there is no obstacle, the controller 110 determines that the body drives abnormally.

The controller 110 may analyze the cause of the abnormal driving based on a current of the motor.

The controller 110 determines that there is an abnormal driving due to the floor condition if the body 10 deviates by a certain distance or more from the movement path while the motor is operating normally and there is no obstacle.

The controller 110 may determine the material of the floor surface based on the current value of the motor. If the abnormal driving occurs continuously, it may be determined that it is due to the floor material and the controller may change the driving according to the material of the floor surface.

The controller 110 may determine that the abnormal driving occurs at a specific location due to a foreign substance. For example, the controller 110 may determine that slipping occurred due to a foreign substance on the floor surface.

The controller 110 determines the current location when slipping occurs. The controller 110 stores the location where the abnormal driving occurred, i.e., the location where slipping occurred, and sets the location to be re-cleaned. The controller 110 may determine that cleaning of the location was not performed normally due to slipping and that a foreign substance exists to the extent of causing slipping and thus complete cleaning was not performed, and may set the location to be re-cleaned.

When abnormal driving occurs at a plurality of locations, the controller 110 connects locations less than a predetermined distance from each other according to the distance between the locations where abnormal driving occurred, sets the location as an abnormality occurrence area, and sets the location where the abnormality occurred to be re-cleaned.

The controller 110 may set the location where the abnormality occurred to be re-cleaned after cleaning of other areas is completed. In addition, the controller 110 may be set to immediately re-clean the location where the abnormality occurred and clean the remaining area.

In some cases, the controller 110 may selectively perform re-cleaning according to a user command input from the terminal while transmitting a notification of the abnormality to the terminal.

The controller 110 may be set to perform cleaning again while driving on a movement path different from the current movement path during re-cleaning.

In addition, the controller 110 may generate a notification and request a replacement of the cleaning cloth when abnormal driving occurs. The controller 110 may perform cleaning again when the cleaning cloth is replaced.

Meanwhile, when abnormal driving occurs, especially when it is determined that slipping has occurred, the controller 110 may perform compensatory driving in preparation for slipping due to the floor material or foreign substances on the floor.

For example, when driving straight, if slipping to the right occurs, the controller 110 may drive toward the left at a predetermined angle to compensate for slipping to the right. In addition, when the actual movement distance is greater than an intended movement distance, the forward force may be adjusted by controlling the rotation speed to perform compensation driving for slipping.

If there is an abnormality in the driving condition, the controller 110 generates a warning message, warning sound, etc. as a corresponding notification and outputs the same through the output part 190. The controller 110 may display a warning by a combination of at least one of a message, an icon, and an image on a control panel provided in an upper portion of the body 10 and may turn on a warning light, and may also output voice guidance.

In the case of driving normally, the controller 110 controls to clean the floor surface while driving in a designated area according to a previously input cleaning command.

If there is an abnormality in the driving condition, the controller 110 sets re-cleaning to be performed according to the cause. The controller 110 outputs a notification regarding the re-cleaning through the output part when re-cleaning is performed.

In addition, if there is an abnormality in the driving condition, the controller 110 may stop the operation. The controller 110 stops operation when it is determined that the cleaning cloth is not installed or that there is a problem with the motor or driver.

In addition, the controller 110 generates a warning according to the occurrence of an abnormality through the communication part 130 and transmits the warning to the terminal 300.

If the controller 110 determines that there is an abnormality in the driving state, the controller 110 stores the location where the abnormality occurred and displays the corresponding location on a map. The controller 110 transmits data regarding the location where the abnormal driving occurred to the terminal 300 so that the location is displayed on the map on the screen through the terminal.

The terminal 300 displays the location where the abnormal driving occurred on the map based on the data received from the controller 110. In addition, the terminal 300 may display a message regarding replacing the cleaning cloth based on the received data.

When the controller 110 stops operation, if a cleaning command is input again from the input part or the terminal 300, the controller 110 may retry driving and re-determine the driving status.

The controller 110 may recognize voice by analyzing a sound input through the audio input part. In some cases, the controller 110 may recognize the input voice by transmitting the input sound to a voice recognition server (not shown). When the voice recognition is completed, the controller 110 performs an operation corresponding to the voice command.

In addition, the controller 110 outputs a voice guidance corresponding to the voice command through the speaker of the output part 190.

The controller 110 checks a charging capacity of the battery and determines the time to return to the charging station. When the charging capacity reaches a certain value, the controller 110 stops the operation being performed and starts searching for the charging station to return to the charging station. The controller 110 may output a notification regarding the charging capacity of the battery and a notification regarding return to the charging station. In addition, when a signal transmitted from the charging station is received through the communication part 130, the controller 110 may return to the charging station.

The controller 110 includes an obstacle recognizer 111, a map generator 112, driving controllers 110 and 113, and a location recognizer 114.

The map generator 112 generates a map for an area based on obstacle information during initial operation or when a map for the area is not stored, while driving through the area.

In addition, the map generator 112 updates a previously generated map based on obstacle information acquired during driving. In addition, the map generator 112 analyzes an image acquired during driving to determine the shape of the area and generates a map.

After generating a basic map, the map generator 112 divides a cleaning area into a plurality of areas, includes a connecting passage connecting the plurality of areas, and generates a map including information on obstacles in each area.

The map generator 112 processes the shape of each divided area. The map generator 112 may set attributes for the divided area.

In addition, the map generator 112 may divide the area from features extracted from the image. The map generator 112 may determine a location of a door based on the connection relationship of the features and may generate a map including a plurality of areas by dividing the boundary between areas accordingly.

The obstacle recognizer 111 determines an obstacle through data input from the image acquisition part 170 or the obstacle detector 100, and the map generator 112 generates a map for the driving area and includes information on the detected obstacle in the map.

The obstacle recognizer 111 analyzes the data input from the obstacle detector 100 to determine the obstacle. The obstacle recognizer 111 calculates a direction of the obstacle or a distance to the obstacle according to a detection signal of the obstacle detector, such as an ultrasonic or laser signal. In addition, the obstacle recognizer may analyze the acquired image including a pattern to extract the pattern and analyze the shape of the pattern to determine the obstacle. In the case of using an ultrasonic or infrared signal, the shape of a received ultrasonic wave and the time at which the ultrasonic wave is received may differ depending on the distance to the obstacle or the location of the obstacle, and thus the obstacle recognizer 111 determines the obstacle based thereon.

The obstacle recognizer 111 may analyze the image captured by the image acquisition part 170 to determine the obstacles located around the body.

The obstacle recognizer 111 may detect a human body. The obstacle recognizer 111 analyzes data input through the obstacle detector 100 or the image acquisition part 170 to detect a human body based on a silhouette, size, face shape, etc., and determines whether the corresponding human body is a registered user.

The obstacle recognizer 111 analyzes the image data to extract the features of the obstacle, determines the obstacle based on the shape (type), size, and color of the obstacle, and determines a location thereof.

The obstacle recognizer 111 may determine the type of obstacle by extracting the features of the obstacle based on the previously stored obstacle data, excluding the background of the image from the image data. The obstacle data is updated by new obstacle data received from the server. The mobile robot 1 may store obstacle data for the detected obstacle and receive data on the types of obstacles from the server for other data.

In addition, the obstacle recognizer 111 stores information on the recognized obstacle in the obstacle data and transmits recognizable image data to the server (not shown) through the communication part 130 so that the type of obstacle may be determined. The communication part 130 transmits at least one image data to the server.

The obstacle recognizer 111 determines the obstacle based on the image data converted by an image processor.

The location recognizer 114 calculates the current location of the body.

The location recognizer 114 may determine the current location based on a signal received using an equipped location recognition device, such as GPS, UWB, etc.

In addition, the location recognizer 114 may extract features from the image of the image acquisition unit, i.e., image data, and compare the features to determine the current location. The location recognizer 114 may determine the current location using a structure around the body, the shape of the ceiling, etc. from the image.

The location recognizer 114 detects features, such as points, lines, and planes, for certain pixels configuring the image and analyzes the features of the area based on the detected features to determine the location. The location recognizer 114 may extract the outline of the ceiling and extract features, such as lighting.

The location recognizer continuously determines the current location within the area through image data, matches the features, learns by reflecting the changes in the surrounding structures, and calculates the location.

The driving controllers 110 and 113 drive through the area based on the map, and control to drive by passing through or avoid the obstacle by changing the movement direction or the driving path in response to the detected obstacle information.

The driving controllers 110 and 113 control the cleaning part 180 according to the cleaning command so that the body 10 performs cleaning by removing foreign substances on the floor surface, while driving through the cleaning area.

The driving controllers 110 and 113 control the driver (not shown) of the cleaning part 180 to independently control the operations of the first rotary plate 81 and the second rotary plate 82, thereby allowing the body 10 to drive straight or rotate.

The driving controllers 110 and 113 control the body to move to a set area or to move within the set area based on the map generated by the map generator 112. In addition, the driving controllers 110 and 113 control driving based on the current location calculated from the location recognizer 114.

The driving controllers 110 and 113 control driving by performing a predetermined operation or changing the driving path in response to an obstacle according to a detection signal from the obstacle detector 100.

The driving controllers 110 and 113 control the body to perform a setting for avoidance, approach, and an approach distance and at least one of stop, deceleration, acceleration, reverse driving, U-turn, and change of driving direction in response to the detected obstacle.

The driving controllers 110 and 113 determine the driving status based on information on a change in location received from the location recognizer, and generates an error in response to abnormal driving.

If there is an abnormality in the driving status, the driving controllers 110 and 113 may determine the cause, maintain or stop the operation in response to the cause, and may also perform compensation driving. For example, if an abnormality occurs in the driving status due to the absence of a cleaning cloth, the driving controllers 110 and 113 may stop the operation and output a notification regarding the absence of the cleaning cloth. In addition, if a location change of a certain size or more occurs due to the material of the floor or foreign substances on the floor, for example, if slipping occurs, the location information is stored and compensation driving for the slipping is performed.

When abnormal driving occurs, the driving controllers 110 and 113 may determine whether driving is possible and if driving is possible, the body may return to the movement path and drives, and if driving is impossible, the driving controllers 110 and 113 stop the operation.

In addition, the driving controllers 110 and 113 may output an error and output a predetermined warning sound or voice guidance as needed.

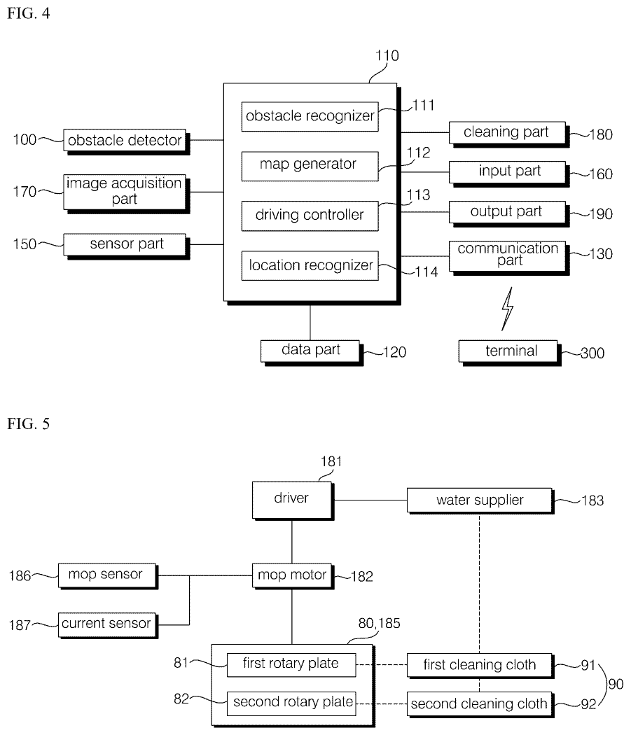

FIG. 5 is a block diagram briefly illustrating the configuration of a cleaning part of a mobile robot according to an embodiment of the present disclosure.

As illustrated in FIG. 5, the cleaning part 180 moves the body 10, while cleaning the floor surface.

The cleaning part 180 includes a driver 181, a cleaning cloth 90, a rotary mops 80 and 185, a water supplier, and a mop motor. In addition, the cleaning part 180 may further include a mop sensor 186 and a current sensor 187. As another example, the cleaning part 180 may include only the current sensor 187.

The rotary mop 185 is connected to a rotating shaft of the mop motor and rotates.

The rotary mop 185 includes the first rotary plate 81 and the second rotary plate 82.

In addition, the rotary mop 185 may further include an adjusting part (not shown) that adjusts a distance between the casing and the first rotary plate 81 and the second rotary plate 82 so that the cleaning cloths 90 (91 and 92) mounted on the first rotary plate 81 and the second rotary plate 82 respectively contact the floor surface. The adjusting part may apply pressure having a certain size so that the first rotary plate 81 and the second rotary plate 82 contact the floor surface. Accordingly, the cleaning cloths are mounted on the first rotary plate 81 and the second rotary plate 82 so that they contact the floor surface regardless of the thickness.

The first rotary plate 81 and the second rotary plate 82 may be configured so that the first and second cleaning cloths 91 and 92 are directly mounted on each of them. For example, Velcro may be attached to the first rotary plate 81 and the second rotary plate 82, so that a cleaning cloth may be fixed thereto.

In addition, the first rotary plate 81 and the second rotary plate 82 may be equipped with a cleaning port (not shown). The cleaning cloth is fitted into the cleaning port frame and mounted on the first rotary plate 81 and the second rotary plate 82.

The first rotary plate 81 and the second rotary plate 82 independently rotate and operate. The driver may control the first rotary plate 81 and the second rotary plate 82 to rotate according to different patterns.

The first rotary plate 81 and the second rotary plate 82 are connected to a rotating shaft of the motor, rotate, and operate in different directions and at different rotation speeds, respectively.

The driver 181 controls the rotation speed, driving, and stopping of the mob motor in response to control commands of the driving controllers 110 and 113. The driver 181 supplies operating power for driving the motor.

The driver 181 operates when the body 10 moves to a destination along a movement path or cleans a designated area.

The driver 181 controls the mob motor so that the first and second rotary plates independently rotate. The driver 181 determines whether the first and second rotary plates 81 operate and a rotation speed according to the shape of the movement path or area and the size and location of the obstacle and controls the mob motor.

The mob motor transmits rotating power to the first and second rotary plates. The mob motor may be provided in plurality. For example, a first mop motor (not shown) may be connected to the first rotary plate, and a second mop motor (not shown) may be connected to the second rotary plate.

A mop motor 182 rotates the first rotary plate 81 in the first direction and rotates the second rotary plate 82 in the second direction, which is opposite direction of the first direction, thereby causing the body 10 to move forward.

In addition, when the body 10 moves to the left or right according to the movement path, the mop motor 182 causes the body 10 to move by changing the rotation of the first rotary plate and the second rotary plate. The motor may rotate the body 10 by causing one side of the first rotary plate and the second rotary plate to stop and the other side to rotate.

The water supplier 183 supplies water contained in the water tank 32 to the cleaning cloth 90. The water supplier supplies water to the cleaning cloth while the body 10 is cleaning, so that the cleaning cloth remains wet.

The water supplier 183 supplies a specified amount of water to the cleaning cloth for a certain period of time. The water supplier 183 includes a connecting path (not shown) connecting the cleaning cloth 90 and the water tank 32.

The water supplier 183 may stop water supply when the motor is stopped by the driver 181. The water supplier 183 may include a valve (not shown) that controls water supply to the cleaning cloth. In addition, the water supplier 183 may include a pump (not shown) that controls water supply from the water tank to the cleaning cloth.

When the operation is stopped, the controller 110 may stop the operation of the pump or close the valve to block the supply of water to the cleaning cloth.

The mop sensor 186 measures the revolutions per minute (RPM) of the mop motor 182 and provides the same to the controller 110.

The current sensor 187 measures a current value of the mop motor 182 and provides the same to the controller 110.

The controller 110 determines whether to replace the cleaning cloth and the time of replacement based on the RPM of the mop motor 182 and the current value of the mop motor 182.

For example, the controller 110 may determine whether to output a cleaning cloth replacement signal notifying about the replacement of the cleaning cloth based on the current value of the current sensor 187.

Specifically, the controller 110 may output the cleaning cloth replacement signal when the measured current value of the mop motor 182 is less than a reference current value, while rotating the mop motor 182 at a reference RPM.

More specifically, the controller 110 may measure the current value of the mop motor 182 a certain number of times for a certain period of time while rotating the mop motor 182 at the reference RPM and define an average value of the current values of the mop motor 182 measured for a certain period of time as a current value of the mop motor 182.

Preferably, the controller 110 may measure the current value of the mop motor 182, while rotating the mop motor 182 at 130 RPM.

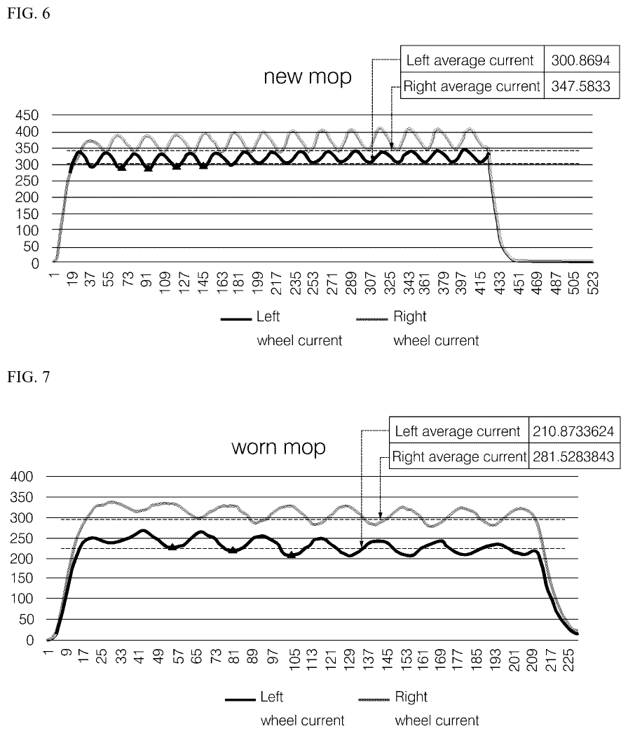

As illustrated in FIG. 6, in the case of a cleaner equipped with a new cleaning cloth, when the mop motor 182 is rotated at 130 RPM, an average current value of the left mop motor 182 is 300 mA and an average current value of the right mop motor 182 is 347 mA. The current value of the mop motor with a new cleaning cloth attached may be defined as an initial current value of the mop motor 182.

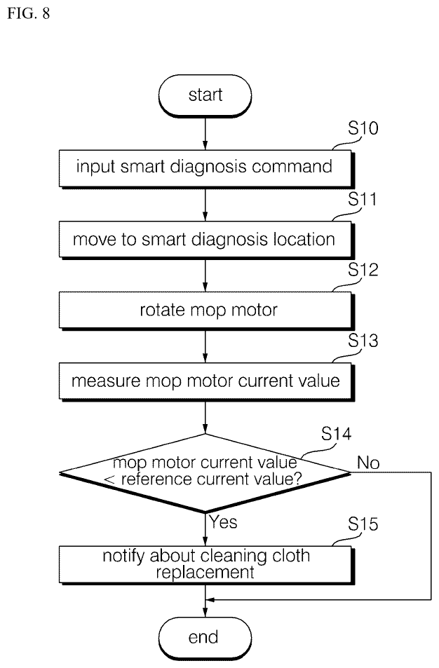

As shown in FIG. 7, in the case of a cleaner with a worn cleaning cloth, when the mop motor 182 is rotated at 130 RPM, an average current value of the left mop motor 182 is 210 mA and an average current value of the right mop motor 182 is 281 mA.

That is, it can be seen that frictional force between the cleaning cloth and the floor decreases depending on the degree of wear of the cleaning cloth, which causes the current value of the mop motor 182 to decrease. Therefore, through the current value of the mop motor 182, the degree of wear of the cleaning cloth may be estimated and the time of replacement of the cleaning cloth may also be estimated.

The reference current value may be a preset value or a value calculated by the cleaner by collecting data.

For example, the reference current value may be a value experimentally obtained based on data tested in advance, which is the current value of a worn cleaning cloth in a general household environment. The reference current value is stored in the data part 120.

In this case, the control is simple to determine the degree of wear of the cleaning cloth, but if the home environment is not typical, an error occurs.

For another example, the reference current value may be a value calculated by the cleaner collecting data. Specifically, the controller 110 may calculate roughness of the floor from the acquired floor image and determines the floor material through the roughness, and the reference current value may be set according to the floor material detected by the floor material detection sensor.

Therefore, since the cleaner detects the floor material while determining the wear of the cleaning cloth, the reference current value according to the previously stored floor material is used, so that the replacement time of the cleaning cloth may be accurately notified regardless of the floor material.

For another example, the reference current value may be set in proportion to the initial current value of the mop motor 182. That is, the controller 110 may measure the initial current value of the mop motor 182 by the user's command and set the reference current value to the measured initial current value.

Specifically, if the initial current value of the mop motor 182 and the reference current value are measured at different locations, it is difficult to accurately measure the wear of the cleaning cloth due to a difference in the material and friction of the floor. Therefore, the controller 110 may control the body so that the initial current value of the mop motor 182 and the reference current value are measured at the same location.

More specifically, the controller 110 may move the body to a preset smart diagnosis location and then measure the initial current value when the initial mop data collection command is input through the input part. The smart diagnosis location may be one of the mounting pad 22 of the charging station, the charging station, and the cleaning area. The initial current value is the current value of the mop motor 182 measured while rotating the mop motor 182 at a reference RPM. The controller 110 may output a cleaning cloth replacement signal when the current value of the mop motor 182 is less than the reference current value, while rotating the mop motor 182 at the reference RPM at the smart diagnosis location.

In addition, the controller 110 may control the current sensor to measure the initial current value of the mop motor 182 when the mop motor 182 is rotated at the reference RPM when an initial mop data collection command is input through the input part. The controller 110 may output the cleaning cloth replacement signal when the current value of the mop motor 182 is less than the reference current value, while rotating the mop motor 182 at the reference RPM at the location where the initial current value is measured.

That is, the controller 110 may move to the original location or the smart diagnosis location and collect the initial current value, when the initial mop data collection command is input.

When the smart diagnosis command is input through the input part, the controller 110 may determine whether to output the cleaning cloth replacement signal and may determine whether to output the cleaning cloth replacement signal at regular intervals.

The controller 110 may transmit the cleaning cloth replacement signal to various components so that the user may recognize the cleaning cloth replacement time in various manners.

For example, the cleaning cloth replacement signal may be a signal that controls ON and OFF of the mop motor 182 repeatedly a preset number of times. The controller 110 may control ON and OFF of the mop motor 182 periodically to allow the user to recognize that it is time to replace the cleaning cloth. In this case, there is an advantage that a separate output part is not required.

In addition, the controller 110 may output a notification to notify the user of the cleaning cloth replacement according to the cleaning cloth replacement signal through the output part. When it is time to replace the cleaning cloth, the controller 110 may notify this with sound through a speaker or with text through a display.

In addition, the controller 110 may control the output part to output the expected lifespan of the cleaning cloth according to the current value of the mop motor 182 when the current value of the mop motor 182 is less than the reference current value, while rotating the mop motor 182 at the reference RPM.

Specifically, when the current value of the mop motor 182 is less than the reference current value, while rotating the mop motor 182 at the reference RPM, the controller 110 may calculate the expected lifespan of the cleaning cloth according to the ratio of the current value of the mop motor 182 to the reference current value and output the same through the output part.

Therefore, the present disclosure not only informs the user of the replacement time of the cleaning cloth but also informs the user of the expected lifespan of the cleaning cloth in advance, so that the user may estimate the replacement time of the cleaning cloth and prepare a replacement cleaning cloth in advance.

In addition, While rotating the mop motor 182 at the reference RPM, if the current value of the mop motor 182 is less than the reference current value, the controller 110 may control to output the expected lifespan of the cleaning cloth and the replacement time of the cleaning cloth to the terminal 300 according to the current value of the mop motor 182.

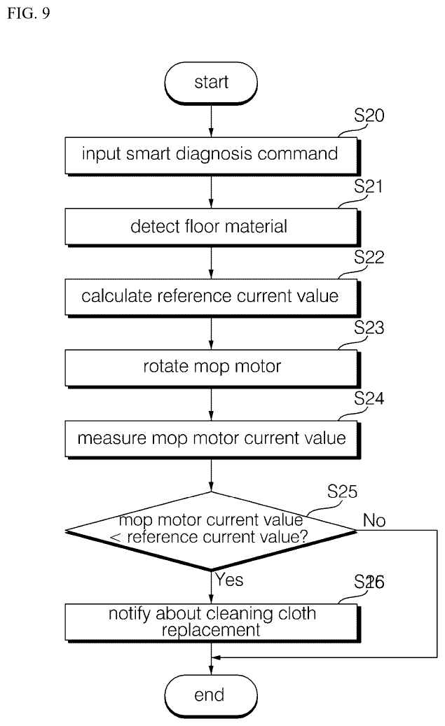

FIG. 8 is a flowchart illustrating a control method of a cleaner according to an embodiment of the present disclosure.

Referring to FIG. 8, the control method of a cleaner according to an embodiment of the present disclosure includes a rotation operation (S12) of rotating the mop motor 182 at a reference RPM, a current measurement operation (S12) of measuring a current value of the mop motor 182 when the mop motor 182 rotates at the reference RPM, and output operations (S13 and S14) of outputting a notification of replacement of the cleaning cloth when the measured current value of the mop motor 182 is less than the reference current value.

When a cleaning command or a command to move to a specific location is input, the mobile robot 1 moves by a rotational motion of the rotary mop 80. The cleaning cloth 90 attached to the rotary mop 80 rotates by the rotary mop to clean the floor surface.

The driver operates the motor in response to a control command of the controller 110 and causes the first rotary plate 81 and the second rotary plate 82 connected to the motor to rotate. The rotation direction and rotation speed of the first rotary plate and the second rotary plate change according to a driving direction.

In a case where the body 10 moves to a specific location, a movement path to a destination is set and the body 10 moves. When cleaning a cleaning area, the body 10 sets a driving pattern corresponding to the size or shape of the area, sets a movement path according to the driving pattern, and then moves. For example, the body 10 may clean by driving in a spiral pattern, a zigzag pattern, or a Y pattern, and may also set a driving pattern for a certain distance from an obstacle.

The controller 110 determines whether a smart diagnosis command is input through the input part of the user (S10).

If a smart diagnosis command is input through the input part of the user, the controller 110 may determine whether to output the cleaning cloth replacement signal.

If a smart diagnosis command is input through the input part of the user, the controller 110 controls the body to move to the smart diagnosis location (S11).

At the smart diagnosis location, the controller 110 rotates the mop motor 182 at the reference RPM (S12), and when the mop motor 182 rotates at the reference RPM, the controller measures the current value of the mop motor 182 (S12).

If the measured current value of the mop motor 182 is less than the reference current value, the controller 110 outputs a notification to notify the replacement of the cleaning cloth (S13, 14).

FIG. 9 is a flowchart illustrating a control method of a cleaner according to another embodiment of the present disclosure.

Referring to FIG. 9, the control method of a cleaner according to an embodiment of the present disclosure includes reference current value calculation operations (S21 and S22) of detecting a floor material and calculating the reference current value, a rotation operation (S23) of rotating the mop motor 182 at a reference RPM, a current measurement operation (S24) of measuring a current value of the mop motor 182 when the mop motor 182 rotates at the reference RPM, and output operations (S25 and S26) of outputting a notification for replacing a cleaning cloth if the measured current value of the mop motor 182 is less than the reference current value.

When a cleaning command or a command to move to a specific location is input, the mobile robot 1 moves by the rotational motion of the rotary mop 80. The cleaning cloth 90 attached to the rotary mop 80 rotates by the rotary mop to clean the floor surface.

The controller 110 determines whether a smart diagnosis command is input through the input part of the user (S20).

When the smart diagnosis command is input through the input part of the user, the controller 110 may determine whether to output the cleaning cloth replacement signal.

When the smart diagnosis command is input through the input part of the user, the controller 110 detects a floor material through the floor detection sensor (S21).

The controller 110 calculates the reference current value based on the detected floor material (S22).

The controller 110 rotates the mop motor 182 at the reference RPM at a location where the floor material is detected (S23), and when the mop motor 182 rotates at the reference RPM, the controller measures a current value of the mop motor 182 (S24).

When the measured current value of the mop motor 182 is less than the reference current value (S25 and S26), the controller 110 outputs a notification to notify the replacement of the cleaning cloth.

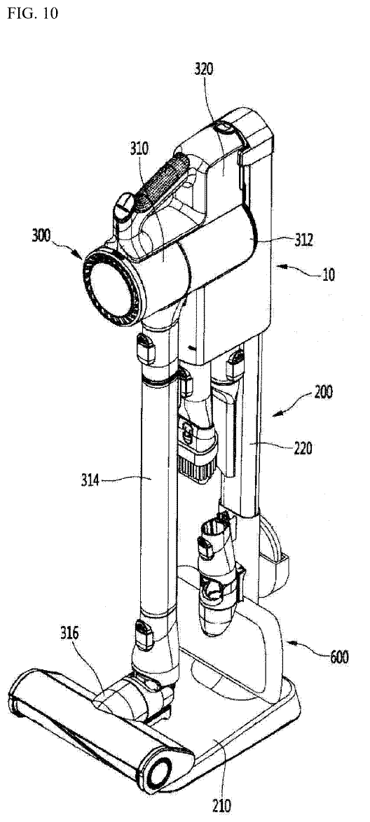

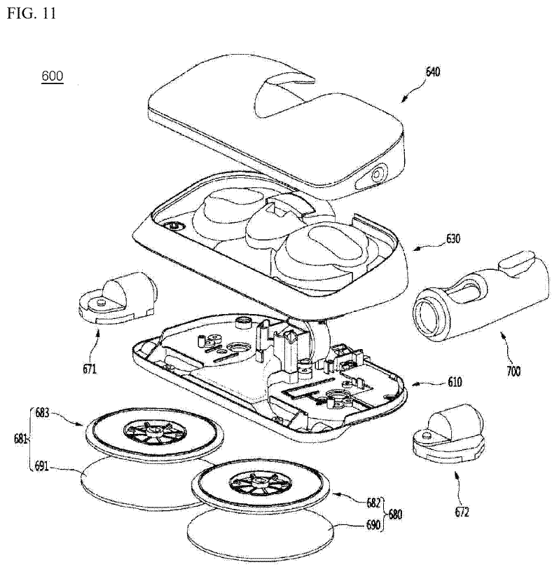

FIG. 10 is a perspective view of a cleaner according to another embodiment of the present disclosure, and FIG. 11 is an exploded perspective view of a water cleaning module of the cleaner illustrated in FIG. 10.

Referring to FIGS. 10 and 11, the cleaner of the present disclosure may include a handheld cleaner.

Referring to FIGS. 10 and 11, a holder 10 of a cleaner according to an aspect of the present disclosure includes a support body 110 for supporting a cleaner 300.

The support body 110 may support the cleaner 300 and charge a battery (not shown) mounted on the cleaner 300.

The cleaner 300 may include a cleaner body 310 equipped with a suction motor and a battery housing 320 that accommodates a battery.

An extension pipe 314 to which a suction nozzle 316 is coupled may be coupled to the cleaner body 310. Air and dust may be sucked in through the suction nozzle 316 by suction force generated by the suction motor.

By the suction force generated by the suction motor, external air is introduced into the cleaner body 310 through the suction nozzle 316 and the extension pipe 314. The cleaner body 310 may be equipped with a dust bin 312 that collects dust included in the air introduced through the suction nozzle 316.

The holder 10 of the cleaner may further include a support unit 200 for supporting the support body.

The support unit 200 may include a base 210 mounted on a floor surface and a stand 220 provided on the base 210.

The stand 220 may be coupled to the upper side of the base 210 and may extend upward. The stand 220 may be detachably coupled to the support body 110.

A water cleaning module 600 capable of sucking air and cleaning the floor surface using a mop soaked in water may be detachably connected to the extension pipe 314 of the cleaner 300.

For example, the water cleaning module 600 may include module housings 610 and 630, a connection pipe 700 provided in the module housings 610 and 630, one or more rotary cleaning parts 680 and 681 rotatably connected to the lower side of the module housings 610 and 630, and one or more driving devices 671 and 672 provided in the module housings 610 and 630 and driving the one or more rotary cleaning parts 680 and 681.

The water cleaning module 600 may further include a water tank 640 mounted on the upper side of the module housings 610 and 630.

Water stored in the water tank 640 may be supplied to the rotary cleaning parts 680 and 681 by passing through the module housings 610 and 630 through the internal path.

The rotary cleaning parts 680 and 681 may include cleaning cloths 690 and 691 and rotary plates 682 and 683 to which the cleaning cloths 690 and 691 are attached. The water in the water tank 640 may be supplied to the mops 690 and 691 by passing through the rotary plates 682 and 683. The rotary plates 682 and 683 are rotated by the mop motor 182 (not shown).

If the user connects the suction nozzle 316 to the extension pipe 314 of the cleaner 300, cleaning may be performed by sucking up dust on the floor.

Meanwhile, when the suction nozzle 316 is separated from the extension pipe 314 of the cleaner 300 and the water cleaning module 600 is connected to the extension pipe 314, dust on the floor surface may be sucked and the floor surface may be water-cleaned.

The mop motor 182, the mop sensor 186, and the current sensor 187 may be installed in the water cleaning module 600. The present disclosure may further include the controller 110 that controls the mop motor 182, the mop sensor 186, and the current sensor 187.

The controller 110 may determine whether to output a cleaning cloth replacement signal that notifies the replacement of the cleaning cloth based on the current value of the mop motor 182 measured by the current sensor 187.

The description is merely an example of the technical idea of the present disclosure, and those skilled in the art will appreciate that various modifications and variations may be made without departing from the essential characteristics of the present disclosure. Accordingly, the embodiments disclosed in the present disclosure are not intended to limit the technical idea of the present disclosure but to explain it, and the scope of the technical idea of the present disclosure is not limited by these embodiments.

[DESCRIPTION OF REFERENCE NUMERALS]

| | |
|---|---|
| 1: mobile robot | 2: charging station |
| 10: body | 32: water tank |
| 40: mop module | 80, 185: rotary mop |
| 90: cleaning cloth | 100: obstacle detector |
| 110: controller | 150: sensor part |
| 160: input part | 170: image acquisition part |
| 180: cleaning part | 181: driver |
| 182: motor | 183: water supplier |
| 190: output part | 300: terminal |

What is claimed is:

1. A cleaner comprising:
a body;
a rotary mop, on which a cleaning cloth is mounted, including a rotary plate rotatably installed on the body;
a mop motor providing driving force to the rotary mop;
a mop sensor measuring revolutions per minute (RPM) of the mop motor;
a current sensor measuring a current value of the mop motor; and
a controller determining whether to output a cleaning cloth replacement signal notifying about replacement of the cleaning cloth based on the current value of the mop motor measured by the current sensor.

2. The cleaner of claim 1, wherein
the controller outputs the cleaning cloth replacement signal when the current value of the mop motor measured while rotating the mop motor at a reference RPM is less than a reference current value.

3. The cleaner of claim 1, further comprising:
a floor material detection sensor detecting a floor material, and the reference current value is set according to a floor material detected by the floor material detection sensor.

4. The cleaner of claim 3, wherein the floor material detection sensor includes a floor camera acquiring a floor image, and the controller calculates roughness of a floor from the acquired floor image and determines a floor material through the roughness.

5. The cleaner of claim 1, wherein the cleaning cloth replacement signal controls ON and OFF of the mop motor repeatedly a preset number of times.

6. The cleaner of claim 1, further comprising:
an output part outputting a notification to notify of cleaning cloth replacement according to the cleaning cloth replacement signal.

7. The cleaner of claim 6, wherein the output part includes at least one of a speaker outputting auditorily recognizable information and a display outputting visually recognizable information.

8. The cleaner of claim 7, wherein the controller controls the output part to output an expected lifespan of the cleaning cloth according to the current value of the mop motor, when the current value of the mop motor is less than a reference current value while rotating the mop motor at a reference RPM.

9. The cleaner of claim 1, further comprising:
an input part receiving a user's command,
wherein the controller determines whether to output the cleaning cloth replacement signal when a smart diagnosis command is input through the input part.

10. The cleaner of claim 9, further comprising:
a sensor part acquiring information on the surroundings of the body,
wherein the controller controls the mop motor to drive the body, and when a smart diagnosis command is input through the input part, the controller moves the body to a preset smart diagnosis location and then determines whether to output the cleaning cloth replacement signal.

11. The cleaner of claim 10, wherein the smart diagnosis location is a charging station charging a battery of the body.

12. The cleaner of claim 1, further comprising:
an input part receiving a user's command,
wherein, when an initial mop data collection command is input through the input part, the controller controls the current sensor to measure an initial current value of the mop motor when the mop motor rotates at a reference RPM.

13. The cleaner of claim 12, wherein the controller, while rotating the mop motor at the reference RPM at the location where the initial current value is measured, outputs the cleaning cloth replacement signal when the current value of the mop motor is less than the reference current value.

14. The cleaner of claim 13, wherein the reference current value is set in proportion to the initial current value.

15. The cleaner of claim 1, further comprising:
a sensor part acquiring information on the surroundings of the body,
wherein the controller controls the mop motor to drive the body, and when the initial mop data collection command is input, the controller moves the body to a preset smart diagnosis location and then measures the initial current value.

16. A cleaner comprising:
a body;
a rotary mop including a rotary plate rotatably installed on the body;
a mop motor providing driving force to the rotary mop;
a current sensor measuring a current value of the mop motor; and
a controller determining whether to output a cleaning cloth replacement signal notifying about replacement of a cleaning cloth based on a current value of the mop motor measured by the current sensor.

17. A control method of a cleaner, the control method comprising:
a rotation operation of rotating a mop motor at a reference revolutions per minute (RPM);
a current measurement operation of measuring a current value of the mop motor when the mop motor rotates at the reference RPM; and
an output operation of outputting a notification for notifying about replacement of the cleaning cloth when the measured current value of the mop motor is less than a reference current value.

18. The control method of claim 17, further comprising:
a reference current value calculation operation of detecting a floor material and calculating the reference current value.

19. The control method of claim 17, further comprising:
a moving operation of moving a body to a smart diagnosis location before the rotation operation.

20. The control method of claim 17, wherein, in the output operation, ON and OFF of the mop motor is repeated a preset number of times.
